(19) United States
(12) Patent Application Publication
(10) Pub. No.: US 2009/0072876 A1
(43) Pub. Date: Mar. 19, 2009

(54) ULTRA-WIDE BAND PULSE SIGNAL GENERATOR

(75) Inventors: Yu Sin KIM, Daejeon (KR); Chang Seok Lee, Deajeon (KR); Kwang Du Lee, Damyang-gun (KR); Chang Soo Yang, Seongnam (KR)

Correspondence Address: LOWE HAUPTMAN HAM & BERNER, LLP, 1700 DIAGONAL ROAD, SUITE 300, ALEXANDRIA, VA, 22314, US

(73) Assignee: Samsung Electro-Mechanics Co., Ltd., Suwon (KR)

(21) Appl. No.: 12/210,127

(22) Filed: Sep. 12, 2008

(30) Foreign Application Priority Data
Sep. 14, 2007 (KR) 10-2007-0093770

(51) Int. Cl. H03K 3/00

(52) U.S. Cl. 327/294

(57) ABSTRACT

There is provided an ultra-wide band pulse signal generator that can vary a waveform and bandwidth of a pulse signal by delaying transmitted data according to a clock signal without using a delay line to generate the pulse signal. An ultra-wide band pulse signal generator according to an aspect of the invention may include: a signal generating unit sequentially delaying transmitted data according to a predetermined clock signal to generate a plurality of pulse signals; an amplification unit amplifying the plurality of pulse signals from the signal generating unit according to predetermined amplification ratios; and a combination unit combining the plurality of pulse signals amplified by the amplification unit.

### CROSS-REFERENCE TO RELATED APPLICATIONS

This application claims the priority of Korean Patent Application No. 2007-0093770 filed on Sep. 14, 2007, in the Korean Intellectual Property Office, the disclosure of which is incorporated herein by reference.

### BACKGROUND OF THE INVENTION

1. Field of the Invention

The present invention relates to ultra-wide band pulse signal generators, and more particularly, to a ultra-wide band pulse signal generator that can vary a waveform and bandwidth of a pulse signal by delaying transmitted data according to a clock signal without using a delay line to generate the pulse signal.

2. Description of the Related Art

An ultra-wide band (UWB) radio communication technology was developed by the Pentagon as a radio communication technology, and has been released to the public by the Federal Communications Commission (FCC).

The ultra-wide band radio communication technology uses a large bandwidth of several GHz, and has attracted attention as a core technology in a next-generation network because of high-speed data transmission and low power consumption, compared to Bluetooth or a wireless local area network based on the IEEE 802.11.

In order to perform ultra-wide band radio communication, there is a need for an ultra-wide band pulse signal generator that generates a UWB pulse train according to data to be transmitted by a transmitter side.

FIG. 1 is a configuration view illustrating an ultra-wide band pulse signal generator according to the related art.

Referring to FIG. 1, according to the related art, an ultra-wide band pulse signal generator 10 adjusts the bandwidth of a UWB pulse signal by using a plurality of OR elements 11 and a delay line 12.

That is, an input pulse signal Vin is supplied as one input to a first OR element 11a. The input pulse signal Vin passes through the delay line 12, is delayed by a predetermined amount of time, and is supplied as the other input to the first OR element 11a. The first OR element 11a performs an OR operation of two input signals, and output pulses each having a predetermined bandwidth to second and third OR elements 11b and 11c. At this time, signal bandwidth of the pulse signal of the first OR element 11a is determined according to the delay time of the delay line 12.

The second and third OR elements 11b and 11c perform an OR operation of the transmitted data and pulse signals from the first OR element 11a, combine results of the OR operation, and output a pulse signal Vout.

According to the related art, the ultra-wide band pulse signal generator 10 adjusts the bandwidth of the pulse signal by using the delay line 12. Here, the bandwidth of the pulse signal is adjusted by changing a length of a transmission line of the delay line 12. Therefore, according to the related art, it is difficult for the ultra-wide band pulse signal generator 10 to finely adjust the bandwidth of the pulse signal.

### SUMMARY OF THE INVENTION

An aspect of the present invention provides an ultra-wide band pulse signal generator that can vary a waveform and bandwidth of a pulse signal by delaying transmitted data according to a clock signal without using a delay line to generating the pulse signal.

According to an aspect of the present invention, there is provided an ultra-wide band pulse signal generator including: a signal generating unit sequentially delaying transmitted data according to a predetermined clock signal to generate a plurality of pulse signals; an amplification unit amplifying the plurality of pulse signals from the signal generating unit according to predetermined amplification ratios; and a combination unit combining the plurality of pulse signals amplified by the amplification unit.

The signal generating unit may include first to N-th (here, N is a natural number) delay elements connected in parallel with each other, the first delay element delays the transmitted data according to the clock signal to output a first pulse signal, the second delay element delays the first pulse signal from the first delay element according to the clock signal to output a second pulse signal, and the third to N-th delay elements each delays a pulse signal from the previous delay element according to the clock signal to output third to N-th pulse signals.

The amplification unit may include first to N-th amplifier elements respectively corresponding to the first to N-th delay elements, and amplifying the pulse signals from the first to N-th delay elements according to the predetermined amplification ratios.

The delay element may be a D flip-flop delaying an input signal for a time interval of the clock signal at a rising edge of the clock signal.

The ultra-wide band pulse signal generator may further include a signal converting unit converting a signal format of the pulse signals combined by the combination unit.

The signal converting unit may be a filter filtering the pulse signals combined by the combination unit within a predetermined bandwidth.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a configuration view illustrating an ultra-wide band pulse generator according to the related art;

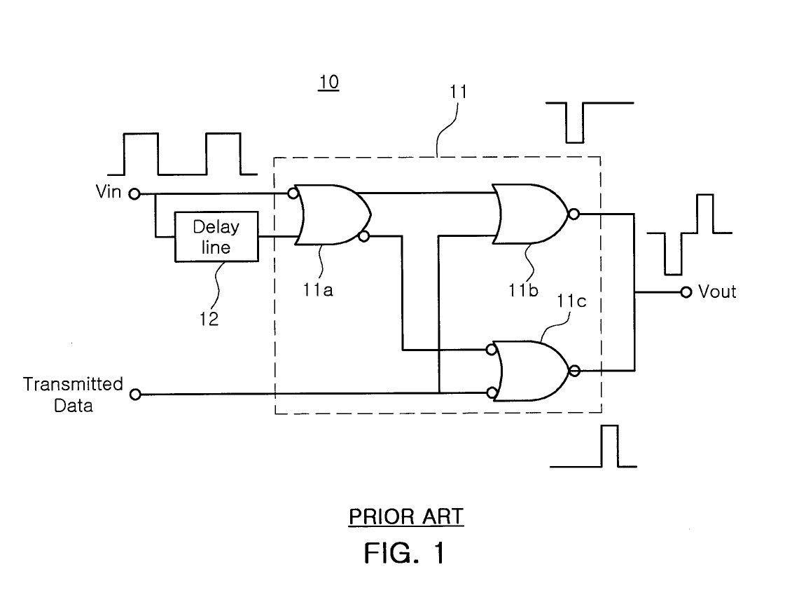

FIG. 2 is a configuration view illustrating an ultra-wide band pulse generator according to an exemplary embodiment of the invention; and

FIGS. 3A to 3C are signal waveform graphs of important parts of the ultra-wide band pulse generator according to the embodiment of the invention.

### DETAILED DESCRIPTION OF THE PREFERRED EMBODIMENT

Exemplary embodiments of the present invention will now be described in detail with reference to the accompanying drawings.

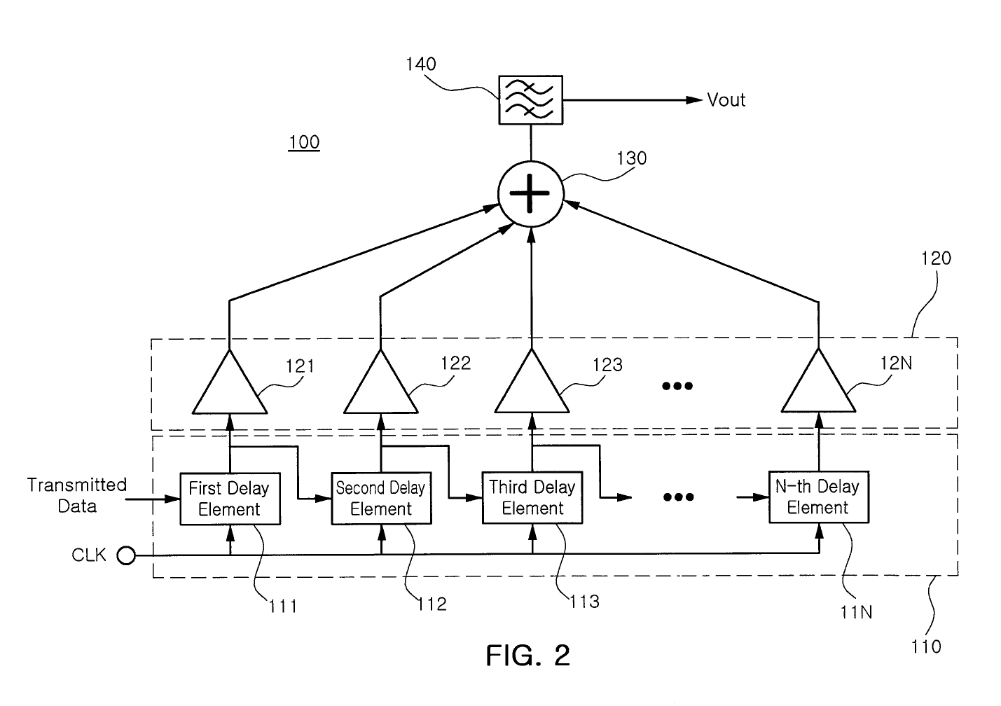

FIG. 2 is a configuration view illustrating an ultra-wide band pulse signal generator according to an exemplary embodiment of the invention.

Referring to FIG. 2, according to this embodiment, an ultra-wide band pulse signal generator 100 includes a signal generating unit 110, an amplification unit 120, and a combination unit 130.

The signal generating unit 110 may include a plurality of first to N-th (here, N is a natural number) delay elements 111 to 11N.

The first to N-th delay elements 111 to 11N are connected in parallel with each other. Data to be transmitted is input to an input terminal of the first delay element 111, and each one of the second to N-th delay elements receives an output signal from the previous delay element.

That is, the output signal of the first delay element 111 is supplied to an input terminal of the second delay element 112, an output signal of the second delay element 112 is supplied to an input terminal of a third delay element 113, and an output signal of an N−1-th delay element (not shown), which is the previous delay element to the N-th delay element 11N, may be supplied to an input terminal of the N-th delay element 11N.

Each of the first to N-th delay elements 111 to 11N operates according to a predetermined clock signal clk, shifts the transmitted data, and generates a pulse signal. In this way, each delay element can delay the input signal supplied to the input terminal of each delay element for a time interval of the clock signal clk.

Each of the first to N-th delay elements 111 to 11N may be formed of a D flip-flop or an RS latch.

For example, when the delay element is formed of a D flip-flop, the D flip-flop includes an input terminal through which data is input, a clock input terminal through which a clock signal is input, and an output terminal through which an OR operation is performed on the data from the input terminal to output the data. As described above, the data is delayed by the time interval of the clock signal clk at a rising edge of the clock signal clk to thereby generate a pulse signal.

The amplification unit 120 may include a plurality of first to N-th amplifier elements 121 to 12N.

The first to N-th amplifier elements 121 to 12N sequentially correspond to the first to N-th delay elements 111 to 11N, and amplify the pulse signals from the first to N-th delay elements 111 to 11N, respectively, according to predetermined amplification ratios.

At least some of the first to N-th amplifier elements 121 to 12N may have different amplification ratios from those of other amplifier elements to output various types of output signals. Alternatively, all of the amplifier elements may have different amplification ratios from each other.

The combination unit 130 combines the pulse signals amplified by the first to N-th amplifier elements 121 to 12N of the amplification unit 120 into one pulse train signal.

The pulse train signal is a digital signal obtained by combining the amplified pulse signals, and needs to be converted into an analog signal so that the pulse train signal in an analog format can be transmitted.

Therefore, in this embodiment, the ultra-wide band pulse signal generator may further include a signal converting unit 140.

The signal converting unit 140 passes the pulse train signal from the combination unit 130 within a predetermined bandwidth to convert a signal format of the pulse train signal into an analog signal format.

The signal converting unit 140 maybe formed of a filter. For the accurate conversion of the signal format, the signal converting unit 140 may be formed of a finite impulse response (FIR) filter.

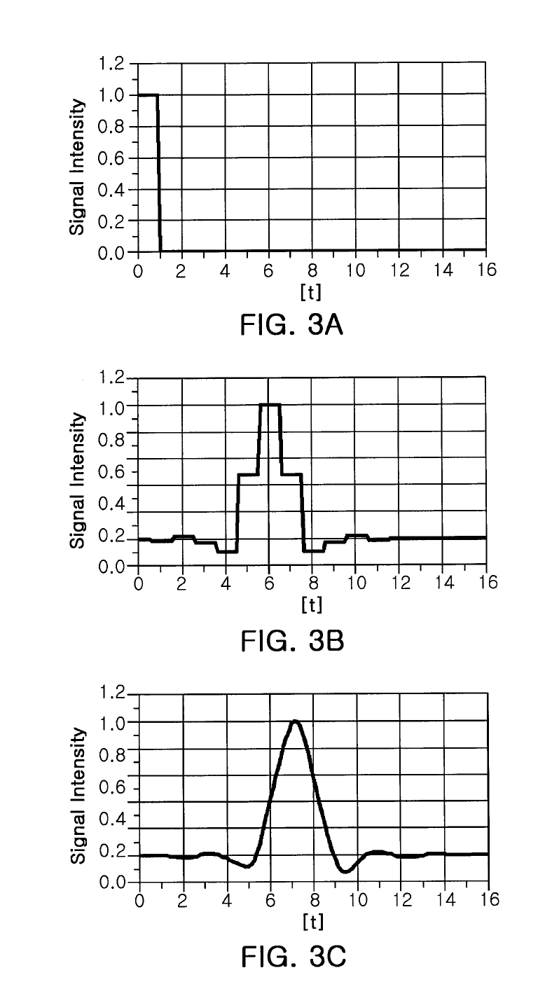

FIGS. 3A, 3B, and 3C are signal waveform graphs of important parts of the ultra-wide band pulse generator according to the embodiment of the invention.

Referring to FIG. 2 and to FIGS. 3A, 3B, and 3C, FIG. 3A is a signal waveform of the transmitted data that is input to the first delay element 111 of the signal generating unit 110.

The first delay element 111 of the signal generating unit 110 receives the transmitted data, delays the data according to the clock signal clk, and outputs a first pulse signal. The first pulse signal is input to the second delay element 112. Then, the second delay element 112 delays the first pulse signal according to the clock signal clk, and outputs a second pulse signal. In the same manner, each of the third to N-th delay elements 113 to 11N delays a pulse signal from the previous delay element according to the clock signal clk, and outputs third to N-th pulse signals.

That is, the signal generating unit 110 sequentially delays the transmitted data according to the clock signal clk to generate the plurality of pulse signals.

The amplification unit 120 includes the first to N-th amplifier elements 121 to 12N respectively corresponding to the first to N-th delay elements 111 to 11N and amplifies the pulse signals from the first to N-th delay elements 111 to 11N according to the predetermined amplification ratios.

The number of delay elements included in the signal generating unit 110 and the number of amplifier elements included in the amplification unit 120 can vary. When the number of delay elements and the number of amplifier elements increase, power consumption increases, but output signals may have various kinds of formats. Further, bandwidth of the output signal can easily be adjusted by changing a time interval of the clock signal clk.

The combination unit 130 combines the pulse signals amplified by the first to N-th amplifier elements 121 to 12N of the amplification unit 120.

In FIG. 3B, the pulse signals amplified by the first to N-th amplifier elements 121 to 12N of the amplification unit 120 are combined into one pulse train signal by the combination unit 130. As described above, the bandwidth and the signal format of the pulse train signal, shown in FIG. 3B, can be controlled by shifting one piece of transmitted data according to the clock signal clk, and amplifying a plurality of pulse signals, generated by shifting the transmitted data, according to different amplification rates.

When the pulse train signal is transmitted, the pulse train signal from the combination unit 130 may be transmitted in an analog format. The ultra-wide band pulse signal generator 100 may further include the signal converting unit 140 to convert the signal format of the pulse train signal from the combination unit 130.

In FIG. 3C, an output signal whose signal format is converted by the signal converting unit 140 is shown.

As shown in FIG. 3C, the signal converting unit 140 passes the pulse train signal from the combination unit 130 within the predetermined frequency bandwidth to convert the signal format into the analog signal format.

As set forth above, according to the exemplary embodiment of the invention, transmitted data is delayed according to a clock signal without using a delay line to generate a pulse signal, such that a waveform and bandwidth of the pulse signal can be easily varied.

While the present invention has been shown and described in connection with the exemplary embodiments, it will be apparent to those skilled in the art that modifications and variations can be made without departing from the spirit and scope of the invention as defined by the appended claims.

What is claimed is:

1. An ultra-wide band pulse signal generator comprising:
a signal generating unit sequentially delaying transmitted data according to a predetermined clock signal to generate a plurality of pulse signals;
an amplification unit amplifying the plurality of pulse signals from the signal generating unit according to predetermined amplification ratios; and
a combination unit combining the pulse signals amplified by the amplification unit.

2. The ultra-wide band pulse signal generator of claim 1, wherein the signal generating unit comprises first to N-th (here, N is a natural number) delay elements connected in parallel with each other,
the first delay element delays the transmitted data according to the clock signal to output a first pulse signal,
the second delay element delays the first pulse signal from the first delay element according to the clock signal to output a second pulse signal, and
the third to N-th delay elements each delays a pulse signal from the previous delay element according to the clock signal to output third to N-th pulse signals.

3. The ultra-wide band pulse signal generator of claim 2, wherein the amplification unit comprises first to N-th amplifier elements respectively corresponding to the first to N-th delay elements, and amplifying the pulse signals from the first to N-th delay elements according to the predetermined amplification ratios.

4. The ultra-wide band pulse signal generator of claim 2, wherein the delay element is a D flip-flop delaying an input signal for a time interval of the clock signal at a rising edge of the clock signal.

5. The ultra-wide band pulse signal generator of claim 1, further comprising a signal converting unit converting a signal format of the pulse signals combined by the combination unit.

6. The ultra-wide band pulse signal generator of claim 5, wherein the signal converting unit is a filter filtering the pulse signals combined by the combination unit within a predetermined bandwidth.
